(19) United States
(12) Patent Application Publication
(10) Pub. No.: US 2022/0020564 A1
(43) Pub. Date: Jan. 20, 2022

(54) PLASMA GENERATING DEVICE

(71) Applicant: AP PLASMA CORPORATION, TAICHUNG CITY (TW)

(72) Inventor: CHIA-CHIANG CHANG, TAOYUAN CITY (TW)

(73) Assignee: AP PLASMA CORPORATION, Taichung City (TW)

(21) Appl. No.: 17/374,532

(22) Filed: Jul. 13, 2021

(30) Foreign Application Priority Data
Jul. 14, 2020 (TW) 109123752

(51) Int. Cl. H01J 37/32

(52) U.S. Cl. CPC H01J 37/3244; H01J 2237/327; H01J 37/32532; H01J 37/32807

(57) ABSTRACT

A plasma generating device includes a plasma sprinkler head and an outer housing, wherein the plasma sprinkler head includes a case and a plasma generating assembly disposed on the case and having a plasma nozzle. The plasma nozzle is located on a side of the case. The outer housing is disposed on the case and is located around the plasma nozzle. In this way, when the plasma nozzle sprays the plasma, the plasma generating device of the present invention could effectively avoid introducing too much external air to affect a quality of the plasma.

### BACKGROUND OF THE INVENTION

### Technical Field

The present invention relates generally to a plasma surface treatment of an object, and more particularly to a plasma generating device.

### Description of Related Art

During production process of objects, surface treatment operations are often applied on objects, such as plasma surface treatment on the surface, wherein the plasma surface treatment operations are performed by spraying plasma (or atmospheric plasma or atmospheric pressure plasma) with the plasma generator, when the plasma contacts a surface of the object, the ions in the plasma induces a physical or chemical reaction on the surface of the object to cause a chemical change or a physical change, achieving the purpose of changing the surface characteristics of the object. For example, it can remove grease and processing residues on the surface of the object to achieve the purpose of cleaning. For example, it can even change a molecular structure of the surface of the object to strengthen the adhesion between the glue and the object when the object adheres to other objects.

A conventional plasma generator 100 is illustrated in FIG. 1 and includes a case 10 and a plasma generating assembly 12 disposed in the case 10, wherein the plasma generating assembly 12 has two electrodes (not shown) and a plasma nozzle 122. The plasma generating assembly 12 communicates with an external gas source (e.g. air, oxygen, nitrogen, and other gases). The two electrodes are connected to a power supply (not shown). The plasma nozzle 122 protrudes out of the case 10. When the power supply provides high-voltage electricity to the two electrodes and gas passes through the two electrodes, the gas forms plasma, and the plasma is sprayed through an output port 122a of the plasma nozzle to perform surface treatment on the object.

When the output port 122a of the plasma nozzle 122 sprays the plasma, a flow rate of the plasma increases, thereby forming a low-pressure area around the output port 122a, and air surrounding the output port 122a will be introduced into the plasma. However, the plasma generator 100 is used under a normal pressure, and climate changes will cause different humidity of the air in the external environment. As a result, air with different humidity will affect a quality of the plasma sprayed by the plasma generator 100. For example, when the air humidity is high, the plasma has high water content and poor quality. In other words, when the plasma is used for the surface treatment of objects, the effect of the treatment will be affected by the ambient air conditions.

### BRIEF SUMMARY OF THE INVENTION

In view of the above, the primary objective of the present invention is to provide a plasma generating device, which could prevent a quality of a plasma from being affected by external air conditions.

The present invention provides a plasma generating device, including a plasma sprinkler head and an outer housing, wherein the plasma sprinkler head includes a case and a plasma generating assembly. The plasma generating assembly is disposed on the case and has a plasma nozzle located on a side of the case. The outer housing is disposed on the case and is located around the plasma nozzle.

With the aforementioned design, by disposing the outer housing around the plasma nozzle, when the plasma nozzle sprays the plasma, the plasma generating device of the present invention could effectively avoid introducing too much external air to affect the quality of the plasma which may result in different processing quality of the object.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic view of the conventional plasma generator;

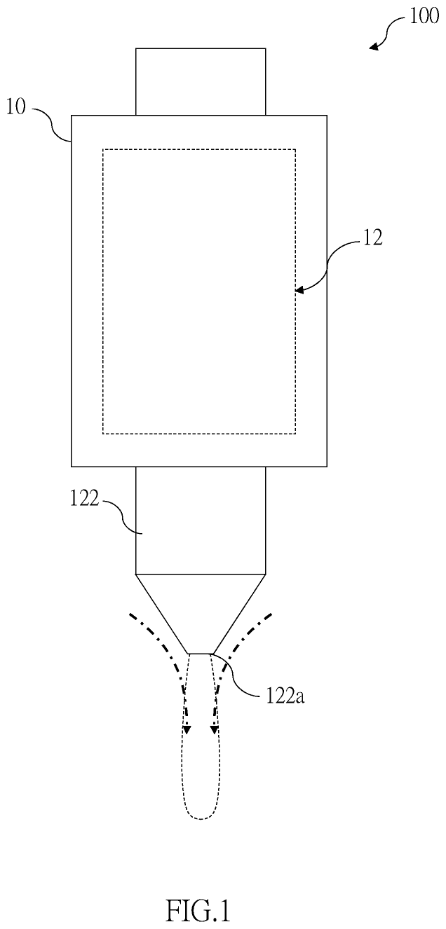

FIG. 2 is a schematic view of the plasma generating device according to a first embodiment of the present invention;

FIG. 3 is a partial sectional schematic view of the plasma generating device according to the first embodiment of the present invention;

FIG. 4 is a schematic view of the plasma generating device according to a second embodiment of the present invention;

FIG. 5 is a schematic view of the plasma generating device according to a third embodiment of the present invention;

FIG. 6 is a partial sectional schematic view of the plasma generating device according to the third embodiment of the present invention seen from another direction;

FIG. 7 is a schematic view of the plasma generating device according to the third embodiment of the present invention, showing the outer housing moves upward;

FIG. 8 is a schematic view of the plasma generating device according to a fourth embodiment of the present invention;

FIG. 9 is a schematic view of the plasma generating device according to the fourth embodiment of the present invention, showing the outer housing moves upward;

FIG. 10 is a schematic view of the plasma generating device according to a fifth embodiment of the present invention;

FIG. 11 is a schematic view of the plasma generating device according to a sixth embodiment of the present invention; and

FIG. 12 is a schematic view of the plasma generating device according to a seventh embodiment of the present invention.

### DETAILED DESCRIPTION OF THE INVENTION

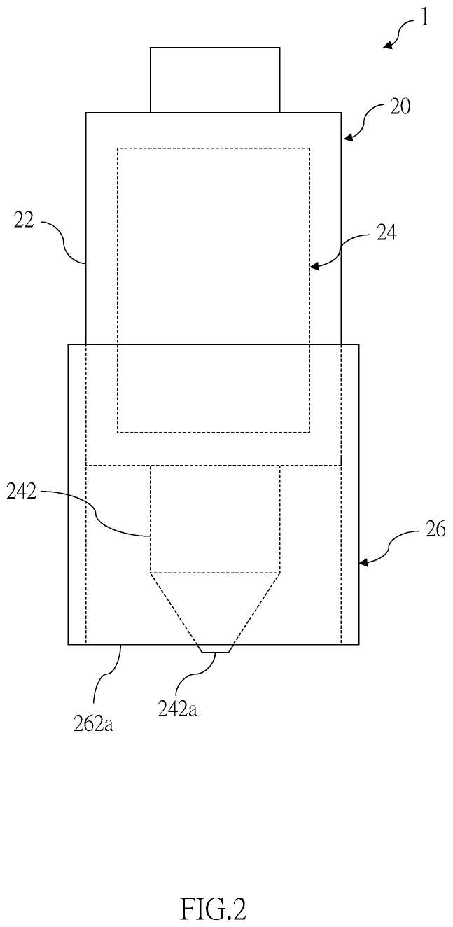

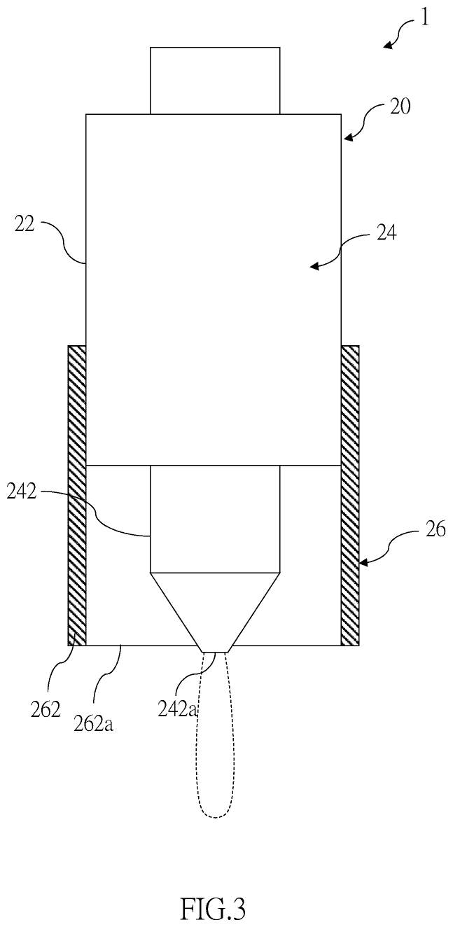

A plasma generating device 1 according to a first embodiment of the present invention is illustrated in FIG. 2 and FIG. 3 and includes a plasma sprinkler head 20 and an outer housing 26.

The plasma sprinkler head 20 includes a case 22 and a plasma generating assembly 24, wherein the case 22 is rectangular shaped and has a chamber therein. However, the case 22 is not limited to rectangular shaped, but could be a cylinder shaped or a polygonal shaped in other embodiments. A part of the plasma generating assembly 24 is disposed in the chamber of the case 22, and communicates with an external gas source (e.g. air, oxygen, nitrogen, and other gases), and has two electrodes (not shown) and a plasma nozzle 242, wherein the two electrodes are connected to a power supply (not shown), and the plasma nozzle 242 protrudes out of a side of the case 22. When the power supply provides a high-voltage electricity to the two electrodes and gas passes through the two electrodes, the gas forms a plasma, and the plasma is sprayed through an output port 242a of the plasma nozzle 242 to perform surface treatment on an object.

The outer housing 26 is disposed on the case 22 and extends to a vicinity of the plasma nozzle 242. In the current embodiment, the outer housing 26 is a rectangular cover, which fits with the case 22, and has a surrounding wall constituted by four sidewalls. In practice, the outer housing 26 could be a cylinder cover, a polygonal cover to fit different shapes of the case 22. A part of the outer housing 26 fits around the case 22, and the surrounding wall 262 surrounds the vicinity of the plasma nozzle 242 and forms an open end 262a at a side of the surrounding wall 262. The outer housing 26 could be made of conductive or non-conductive materials, wherein the conductive material could be, for example, metal, and the non-conductive material could be, for example, plastic, composite material, etc.

At least a part of the plasma nozzle 242 is located between the open end 262a and the case 22. In the current embodiment, the plasma nozzle 242 protrudes out of the open end 262a, so that the output port 242a is located out of the open end 262a.

By disposing the outer housing 26 around the plasma nozzle 242, when the output port 242a of the plasma nozzle 242 sprays the plasma and forms a low-pressure area on a periphery of the output port 242a, air around the outer housing 26 being introduced into the plasma could be reduced, thereby prevent a quality of the plasma being affected by external air conditions.

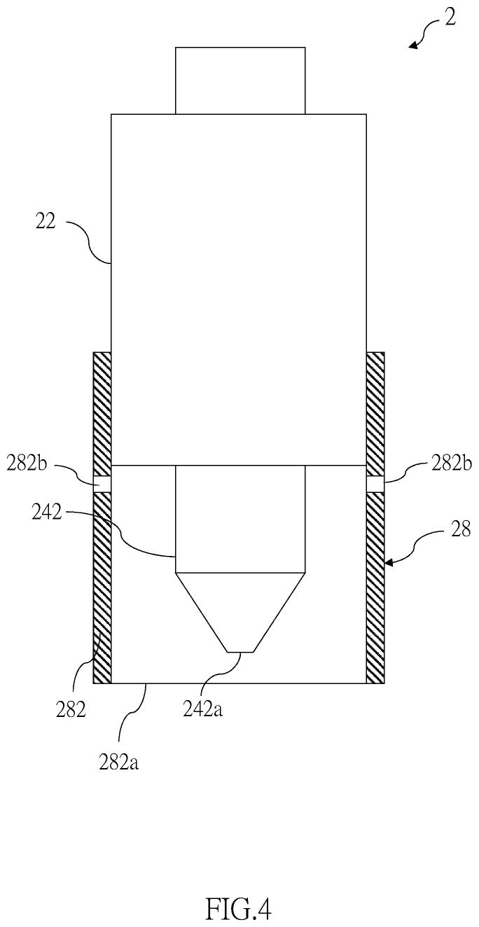

A plasma generating device 2 according to a second embodiment of the present invention is illustrated in FIG. 4, which has almost the same structures as that of the first embodiment, except that the plasma nozzle 242 is entirely located between an open end 282a of an outer housing 28 and the case 22 (i.e., the output port 242a is located in the outer housing 28. Additionally, a plurality of vents 282b is formed on a surrounding wall 282 of the outer housing 28, wherein the vents 282b are located between the open end 282a and the case 22. In practice, the number of the vents 282b could be at least one.

In this way, when the output port 242a of the plasma nozzle 242 sprays a plasma, a small amount of air could be introduced into the outer housing 28 via the vents to balance internal and external pressures of the outer housing 28 to avoid forming a low pressure inside the outer housing 28 which may affect a smoothness of the plasma ejection. For example, the plasma could be prevented from flowing back into the outer housing 28.

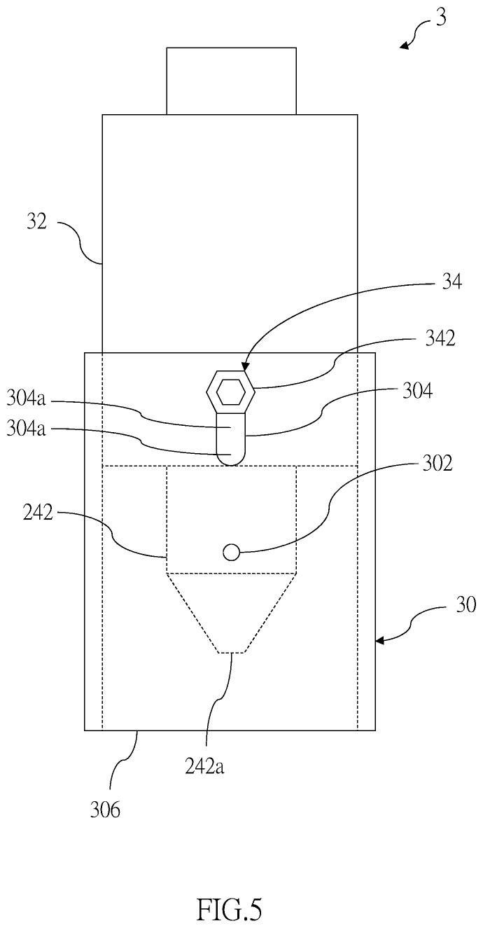

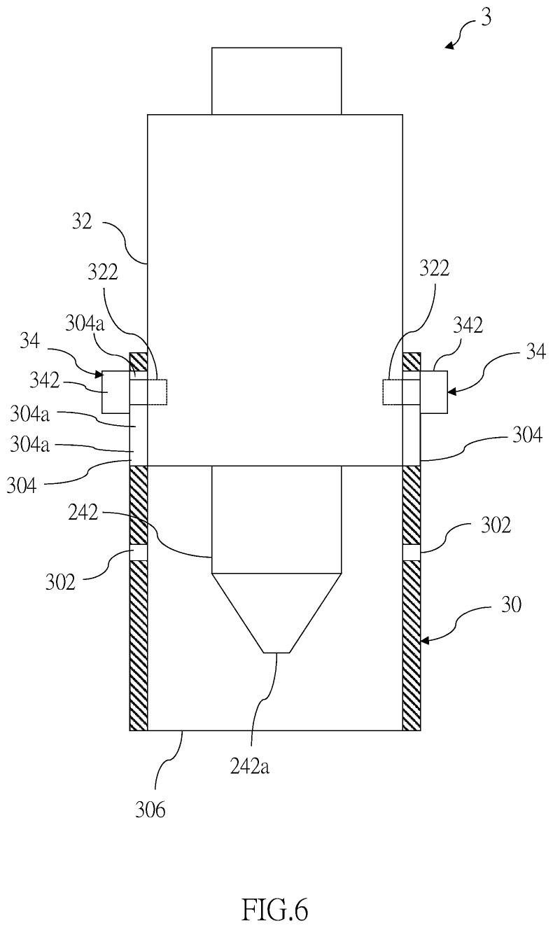

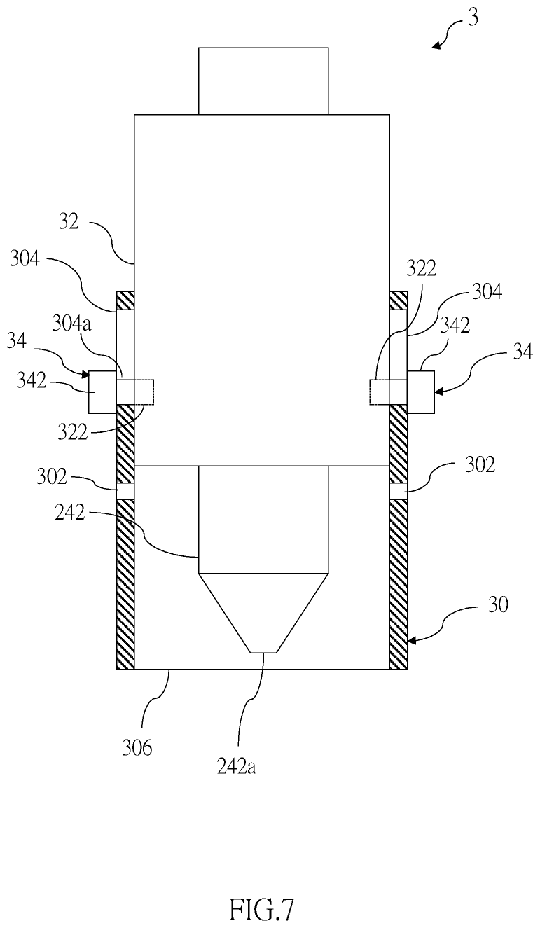

A plasma generating device 3 according to a third embodiment of the present invention is illustrated in FIG. 5 to FIG. 7, which has almost the same structures as that of the second embodiment (e.g. an outer housing 30 has a plurality of vents 302 as well), except that the outer housing 30 is movably disposed on a case 32.

More specifically, the case 32 has a plurality of engaging holes 322, In the current embodiment, each of the engaging holes 322 is a threaded hole. The outer housing 30 has a displacement adjusting structure which is a plurality of elongated slots 304 as an example, wherein a longitudinal direction of each of the elongated slots 304 is parallel to a longitudinal direction of the plasma nozzle 242. Each of the elongated slots 304 has a plurality of hole sections 304a on the longitudinal direction of the elongated slots 304, and the hole sections 304a constitutes a plurality of hollow areas of the displacement adjusting structure. When the outer housing 30 moves up and down, the hole sections of each of the elongated slots 304 could respectively correspond to the engaging holes 322.

In the current embodiment, the plasma generating device 3 further includes a plurality of engaging members 34, wherein each of the engaging members 34 is a bolt and passes through one of the hole sections 304a of each of the elongated slots 304 to be engaged with one of the engaging holes 322, and a head of each of the engaging members 34 abuts against the outer housing 30 to fix the outer housing 30 on the case 32.

In this way, when loosening each of the engaging members 34, a position of the outer housing 30 relative to the case 32 could be adjusted, changing a relative position between an open end 306 of the outer housing 30 and the output port 242a of the plasma nozzle 242, thereby spraying a plasma with different processing effects on an object. For instance, when a humidity of an outside air is high, the outer housing 30 could be moved down to reduce the air introduced into the plasma; when the output port 242a needs to be closer to the object to be processed, the outer housing 30 could be moved up so that the output port 242a is closer to outside of the outer housing 30 or protrudes out of the outer housing 30.

In practice, the number of the engaging holes 322, the number of the engaging members 34, the number of the displacement adjusting structure could be respectively one.

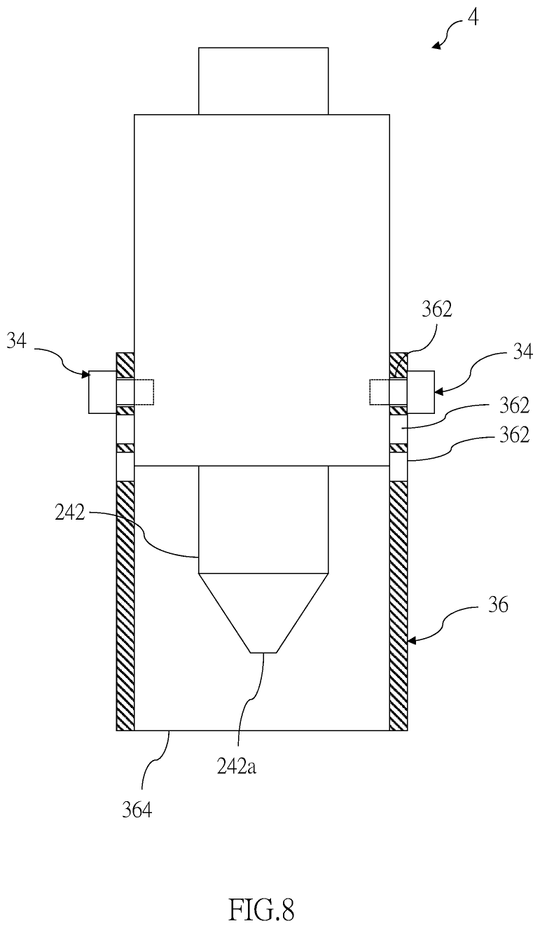

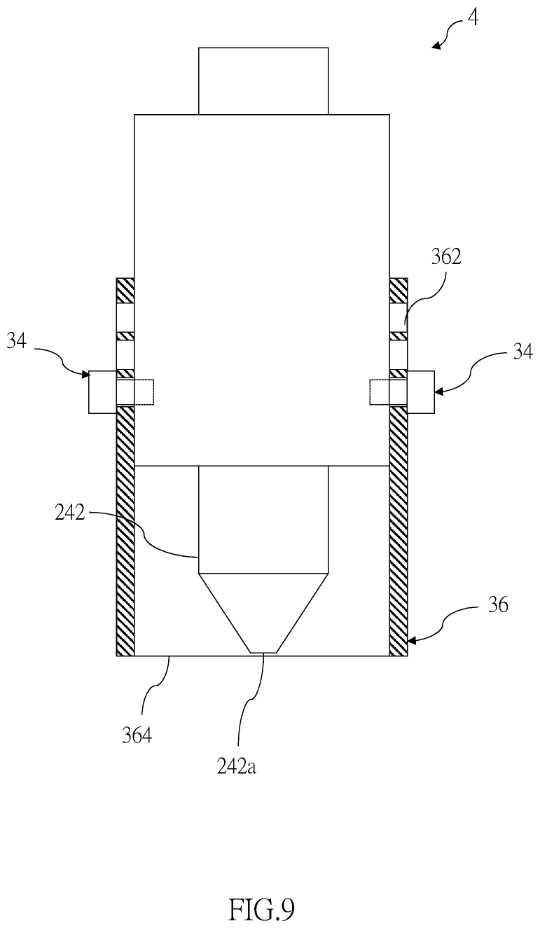

A plasma generating device 4 according to a fourth embodiment of the present invention is illustrated in FIG. 8 and FIG. 9, which has almost the same structures as that of the third embodiment, except that a displacement adjusting structure of an outer housing 36 of the current embodiment is a plurality of perforations arranged along an axis parallel to the longitudinal direction of the plasma nozzle 242, and the perforations 362 constitute a plurality of hollow areas of the displacement adjusting structure.

In this way, the engaging members 34 could also achieve a purpose of fixing the outer housing 36 and adjusting a relative position between an open end 364 of the outer housing 36 and the output port 242a of the plasma nozzle 242, wherein a part of the hollow areas not engaging with the engaging members 34 could form a vent to balance internal and external pressures of the outer housing 36.

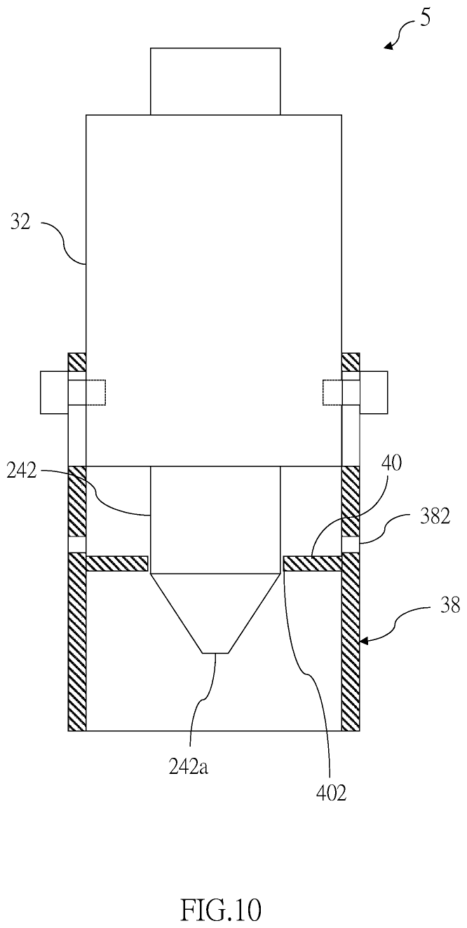

A plasma generating device 5 according to a fifth embodiment of the present invention is illustrated in FIG. 10, which has almost the same structures as that of the third embodiment, except that a plate 40 is disposed inside an outer housing 38, wherein the plate 40 has a through hole 402, and the plasma nozzle 242 passes through the through hole 402, and the plate 40 is located between the output port 242a and the case 32. By disposing the plate 40, the plasma could be prevented from flowing back into the outer housing 38.

Additionally, in the current embodiment, a plurality of vents 382 is disposed between the plate 40 and the case 32, and there is a gap formed between the plasma nozzle 242 and a wall of the through hole 402, so that when the plasma is sprayed, a small amount of air could be introduced into the outer housing 38 via the vents 382 and the gap, thereby balancing internal and external pressures of the outer housing 38.

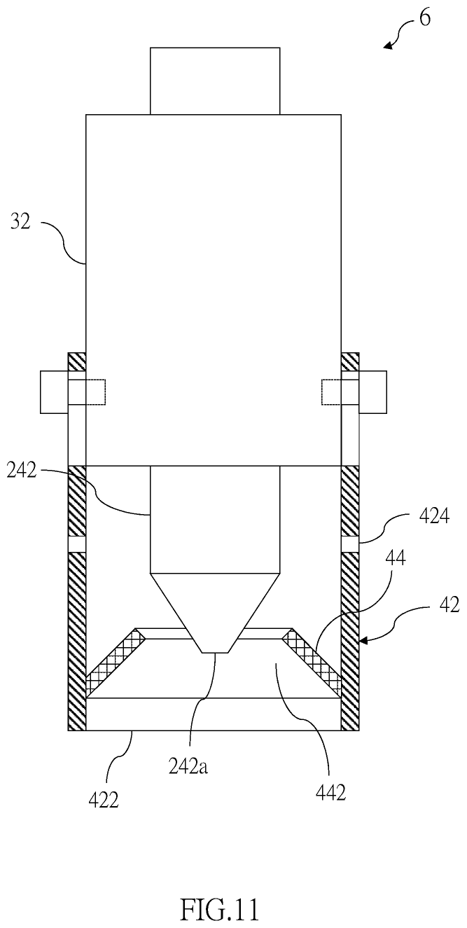

A plasma generating device 6 according to a sixth embodiment of the present invention is illustrated in FIG. 11, which has almost the same structures as that of the third embodiment, except that an inner cover is disposed inside an outer housing 42, wherein the inner cover 44 has a passage 442, and a width of the passage 442 decreases gradually from an open end 422 of the outer housing 42 to the case 32, and the output port 242a of the plasma nozzle 242 is located in the passage 442. With the gradually decreased passage 442 of the inner cover 44, the plasma could be prevented from flowing back into the outer housing 42. In addition, in the current embodiment, a plurality of vents 424 is disposed between the inner cover 44 and the case 32, achieving an effect of balancing internal and external pressures of the outer housing 42.

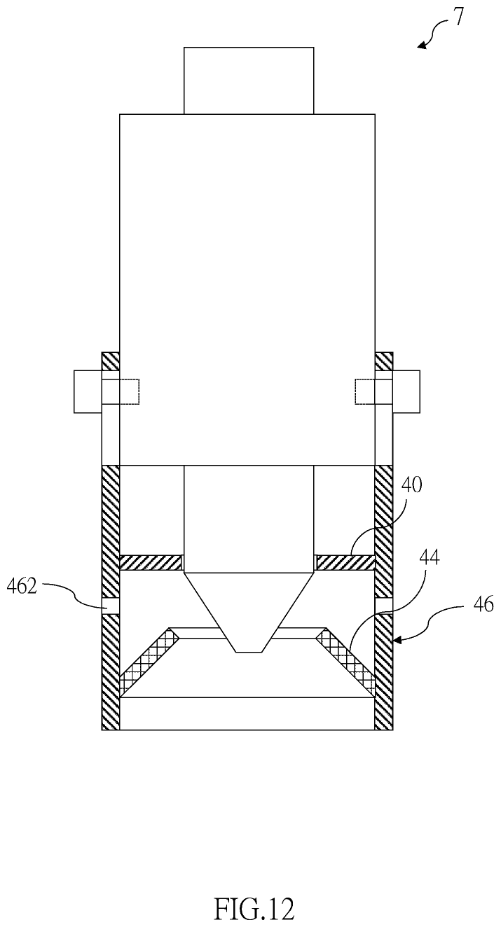

A plasma generating device 7 according to a seventh embodiment of the present invention is illustrated in FIG. 12, which has almost the same structures as that of the fifth embodiment and the sixth embodiment, except that the plate 40 and the inner cover 44 are disposed inside an outer housing 46 of the current embodiment, which could prevent the plasma from flowing back into the outer housing 46 as well. In the current embodiment, a plurality of vents 462 is disposed between the plate 40 and the inner cover 44.

With the aforementioned design, by disposing the outer housing around the plasma nozzle, when the plasma nozzle sprays the plasma, the plasma generating device of the present invention could effectively avoid introducing too much external air to affect the quality of the plasma which may result in different processing quality of the object.

It must be pointed out that the embodiments described above are only some preferred embodiments of the present invention. All equivalent structures which employ the concepts disclosed in this specification and the appended claims should fall within the scope of the present invention.

What is claimed is:

1. A plasma generating device, comprising:
a plasma sprinkler head comprising a case and a plasma generating assembly, wherein the plasma generating assembly is disposed on the case and has a plasma nozzle located on a side of the case; and
an outer housing disposed on the case and located around the plasma nozzle.

2. The plasma generating device as claimed in claim 1, wherein the outer housing has an open end; at least a part of the plasma nozzle is located between the open end and the case.

3. The plasma generating device as claimed in claim 2, wherein the plasma nozzle has an output port located between the open end and the case.

4. The plasma generating device as claimed in claim 2, wherein the plasma nozzle has an output port protruding out of the open end.

5. The plasma generating device as claimed in claim 2, wherein the outer housing has a surrounding wall surrounding around the plasma nozzle and having the open end; the surrounding wall has at least one vent located between the open end and the case.

6. The plasma generating device as claimed in claim 1, wherein the outer housing is movably disposed on the case.

7. The plasma generating device as claimed in claim 6, further comprising at least one engaging members, wherein the case has at least one engaging hole adapted to be engaged with at least one engaging member; the outer housing has at least one displacement adjusting structure having a plurality of hollow areas respectively corresponding to the at least one engaging hole; the at least one engaging member passes through one of the hollow areas of the at least one displacement adjusting structure to be engaged with the at least one engaging hole to fix the outer housing on the case.

8. The plasma generating device as claimed in claim 7, wherein the at least one displacement adjusting structure is an elongated slot; the elongated slot has a plurality of hole sections along a longitudinal direction of the elongated slot which communicates with one another; the hole sections constitute the hollow areas.

9. The plasma generating device as claimed in claim 7, wherein the at least one displacement adjusting structure is a plurality of perforations arranged along an axis; the perforations constitute the hollow areas.

10. The plasma generating device as claimed in claim 1, wherein the plasma nozzle has an output port; a plate is disposed in the outer housing and has a through hole; the plasma nozzle passes through the through hole; the plate is located between the output port and the case.

11. The plasma generating device as claimed in claim 10, wherein the outer housing has a surrounding wall surrounding around the plasma nozzle and having the open end; the surrounding wall has at least one vent located between the plate and the case; a gap is formed between the plasma nozzle and a wall of the through hole.

12. The plasma generating device as claimed in claim 1, wherein an inner cover is disposed in the outer housing and has a passage; the passage decreases gradually from the open end to the case; an output port of the plasma nozzle is located in the passage.

13. The plasma generating device as claimed in claim 12, wherein the outer housing has a surrounding wall surrounding around the plasma nozzle and having the open end; the surrounding wall has at least one vent located between the inner cover and the case.
